(19) United States
(12) Patent Application Publication
(10) Pub. No.: US 2005/0023610 A1
(43) Pub. Date: Feb. 3, 2005

(54) Semiconductor-on-insulator structure having high-temperature elastic constraints

(76) Inventors: Bruno Ghyselen, Seyssinet-Pariset (FR); Cecile Aulnette, Grenoble (FR); Olivier Rayssac, Grenoble (FR)

Correspondence Address: WINSTON & STRAWN;PATENT DEPARTMENT, 1400 L STREET, N.W., WASHINGTON, DC, 20005-3502, US

(21) Appl. No.: 10/700,896

(22) Filed: Nov. 3, 2003

(30) Foreign Application Priority Data
Jul. 30, 2003 (FR) 03 09377

(51) Int. Cl. H01L 27/01

(52) U.S. Cl. 257/347

(57) ABSTRACT

A semiconductor-on-insulator structure for electronics, optics or optoelectronics, in which a semiconductor layer includes desirable elastic constraints. The structure includes a substrate, an insulating layer on the substrate, and a semiconductor layer on the insulating layer. The semiconductor layer has elastic constraints, and the insulating layer is made of an electrically insulating material having a viscosity temperature T_{G} that is sufficiently high so as to protect the semiconductor layer from loss of the elastic constraints when the structure is exposed to a temperature of about 950° C. or more. Also described is a process for producing such a semiconductor-on-insulator structure.

### BACKGROUND ART

The present invention generally relates to a semiconductor-on-insulator structure (or SeOI) designed for electronics, optics or optoelectronics, in which the semiconductor layer comprises elastic constraints. The invention also relates to a process for producing a SeOI structure in which the semiconductor layer comprises elastic constraints. In an implementation according to the invention, a strained semiconductor material film is formed on a wafer in a first stage of the process. A layer of SiO₂ is then formed on the strained film and/or on the surface of a substrate, and the strained film is transferred to the substrate to form a SeOI structure whose semiconductor part includes the strained film and whose electrically insulating part includes the SiO₂ layer.

A layer is strained if its crystalline material is tensed or compressed elastically during crystalline growth, such as during epitaxial growth. This causes its mesh parameter to be substantially different than the nominal mesh parameter of the material. The nominal mesh parameter extends like the mesh parameter of the material in its solid monocrystalline form, and in balance. Conversely, any layer having a crystalline material which has a mesh parameter substantially identical to its nominal mesh parameter is called a ‘relaxed’ layer.

Strained silicon (or Si) layers are mainly of interest because they have an average mobility of charged particles (such as holes and electrons) that is greater than that usually found in layers of relaxed Si. The layers of strained Si can attain a mobility of charged particles that is 100% more significant than that present in layers of relaxed Si.

International Application No. WO 01/99162 describes forming a layer of strained Si on a wafer, and then transferring the strained film by adhering the wafer to a substrate and removing the wafer by etching selectively ‘at the back’ of the wafer (otherwise known as an ‘etch-back’ technique). This method finally produces a Silicon-On-Insulator (or SOI) structure wherein the semiconductor part is the layer of strained Si.

Alternatively, when producing an SOI structure with strained Si, a SMART-CUT® technique that is familiar to one skilled in the art (and which is described in particular in the document entitled ‘Silicon-On-Insulator Technology; Materials to VLSI, 2nd Edition’ by J.-P. Colinge edited by Kluwer Academic Publishers, pages 50 and 51) can be employed during the removal stage in place of the etch-back technique. The latter process is described in particular in the document entitled “Preparation of novel SiGe-free strained Si on insulator” by T. A. Langdo and colleagues (Proceedings of the 2002 IEEE International SOI Conference, Williamsburg, Va. (USA), page 211).

Applications for such SeOI structures, and more particularly SOI structures, most often concern manufacturing electronic, optical or optoelectronic components, such as transistors or diodes, in the strained semiconductor layers. Fabrication of such components often require thermal treatments at raised temperatures. The elastic constraints in the semiconductor part of a SeOI structure must therefore be resistant to the thermal treatment because such treatments are likely to cause significant relaxation of the constraints (which would have an undesirable effect).

A SeOI structure such as that described above substantially relaxes the elastic constraints in its semiconductor part after a certain temperature is reached, which can be on the order of 950° C. to 1000° C. or more in the case of a strained SOI structure. Therefore, the behavior of the elastic constraints in the semiconductor part of a SeOI structure is problematic when it is subjected to a temperature greater than a threshold temperature. In order to preserve desired properties, such as electrical or electronic properties provided by the elastic constraints in such a SeOI structure, components are manufactured at temperatures lower than the threshold temperature. Further, manufacturers may also have to limit the types of components that can be embodied in strained layers of the SeOI structure.

### SUMMARY OF THE INVENTION

The present invention overcomes the difficulties discussed above and provides a semiconductor-on-insulator structure that includes both semiconductor material and electrically insulating material. An implementation of a semiconductor-on-insulator structure according to the invention includes a substrate, an insulating layer on the substrate, and a semiconductor layer on the insulating layer. The semiconductor layer has elastic constraints, and the insulating layer is made of an electrically insulating material to electrically insulate the semiconductor layer from materials that contact the insulating layer, with the material of the insulating layer having a viscosity temperature T_{G} that is sufficiently high so as to protect the semiconductor layer from loss of the elastic constraints when the structure is exposed to a temperature of about 950° C. or more.

In a preferred implementation, the insulating layer has a T_{G} that is at least 1000° C. When the semiconductor layer comprises silicon, the insulating layer preferably has a viscosity temperature T_{G} that is greater than the viscosity temperature T_{GSiO2} of silicon oxide (SiO₂). Such a strained semiconductor layer in a SeOI structure can be advantageously exploited because it includes desirable physical and/or electrical properties.

In an advantageous embodiment, the semiconductor layer comprises a film of strained material. The strained film may be made of Si_{1-y}Ge_{y}, wherein y is between 0 and 1. The structure may further include at least one layer of relaxed or pseudo-relaxed material on the strained film, and such a layer may be located between the strained film and the insulating layer. Alternately, the strained film may be located between the layer of relaxed or pseudo-relaxed semiconductor material and the insulating layer. In a variation, a first layer of a relaxed or pseudo-relaxed material is situated between the strained film and the insulating layer and a second layer of relaxed or pseudo-relaxed material is situated on an opposite side of the strained film. The relaxed or pseudo-relaxed material could be made of Si₁₋ₓGeₓ, where x is between 0 and 1.

In another advantageous implementation, the viscosity temperature T_{GsiO2} is greater than approximately 1100° C. In addition, the insulating layer is made of SiO_{y}N_{z} where y and z can vary from 0 to an integer, e.g., Si₃N₄, but both y and z cannot be 0 simultaneously. The insulating layer may also be made of Si_{1-z}Ge_{z}, wherein z is between 0 and 1. The semiconductor layer preferably includes a strained Si_{1-y}Ge_{y} layer, and a layer of relaxed or pseudo-relaxed Si₁₋ₓGeₓ on the strained layer, wherein x and y are between 0 and 1 and are not equal to each other. An alternate embodiment includes a semiconductor layer having a layer of relaxed or pseudo-relaxed Si_{1-z}Ge_{z}, a layer of strained Si_{1-y}Ge_{y}, and a layer of relaxed or pseudo-relaxed Si₁₋ₓGeₓ wherein x, y and z are between 0 and 1, x, y and z are not equal to each other, and x and y are approximately the same value.

A further aspect of the invention concerns a process for producing a semiconductor-on-insulator structure. The technique includes growing a strained layer of semiconductor material on a donor wafer of crystalline material having a first mesh parameter, the semiconductor material selected to have a nominal mesh parameter that is substantially different from the first mesh parameter. The strained layer is grown to a thickness that is sufficiently thin so that it is elastically strained. Next, at least one layer of electrically insulating material having a viscosity temperature T_{G} greater than the viscosity temperature T_{GSiO2} of silicon oxide (SiO₂) is formed on at least one of the strained layer and on a surface of a receptor substrate. The receptor substrate is then bonded to the donor wafer such that the strained and the insulator layers are positioned between the receptor substrate and the donor wafer, and at least a portion of the donor wafer is detached to form the semiconductor-on-insulator structure.

In an advantageous implementation, the process includes growing a relaxed or pseudo-relaxed layer of a material selected from semiconductor materials, on the strained layer. The electrically insulating layer can be formed by nitration, and the insulating layer may be deposited on at least one surface to be bonded.

In another variation, the process further includes transferring a portion of the donor wafer to the receptor substrate to form at least a part of an upper layer of crystalline material. The method may further include, before the transfer, implanting atomic particles into the donor wafer at a preset depth to create a weakened zone in the vicinity of the depth of the implant so that detachment occurs at the weakened zone. Alternatively, the process may include, prior to growing the strained layer, forming a porous layer on a crystalline support substrate, growing a crystalline layer on the porous layer, wherein the support substrate, porous layer and crystalline layer together forming the donor wafer, and the porous layer being a weakened zone in the donor wafer so that detachment occurs at the weakened zone. The technique may beneficially include finishing the surface of the portion of the donor wafer that is transferred to the receptor substrate, or removing the portion of the donor wafer transferred to the receptor substrate. A selective chemical etching process could be used to remove the portion of the donor wafer with respect to the semiconductor material of the strained layer.

### BRIEF DESCRIPTION OF THE DRAWINGS

Other aspects, purposes and advantages of the invention will become clear after reading the following detailed description with reference to the attached drawings, in which:

FIGS. 1a to 1d illustrate the different stages of a first process for realizing an electronic structure including a thin layer of strained silicon according to the present invention.

FIGS. 2a to 2d illustrate the different stages of a second process for realizing an electronic structure including a thin layer of strained silicon according to the present invention.

FIGS. 3a to 3e illustrate the different stages of a third process for realizing an electronic structure including a thin layer of strained silicon according to the present invention.

FIGS. 4a to 4e illustrate the different stages of a fourth process for realizing an electronic structure including a thin layer of strained silicon according to the present invention.

### DETAILED DESCRIPTION OF THE PREFERRED EMBODIMENTS

The present method permits the formation of a film of strained semiconductor material on a substrate. In addition, the method is a reliable process for transferring a film of strained material of a donor wafer to a receptor substrate, to form a desired electronic structure, without relaxing the constraint inside the film during transfer. In terms of implementing the transfer process of the strained film, the method also results in a SeOI structure wherein the semiconductor part includes elastic constraints, and the behavior of these constraints is conserved during thermal treatment at high temperature. In a particular case, the relative behavior of the constraints of a layer of strained Si of a SeOI structure is conserved during thermal treatment at temperatures greater than about 950° C. to about 1000° C.

Such thermal treatment can be employed during processing and then could be carried out after or during formation of the strained film. For example, thermal treatment could be used to fabricate components in the film.

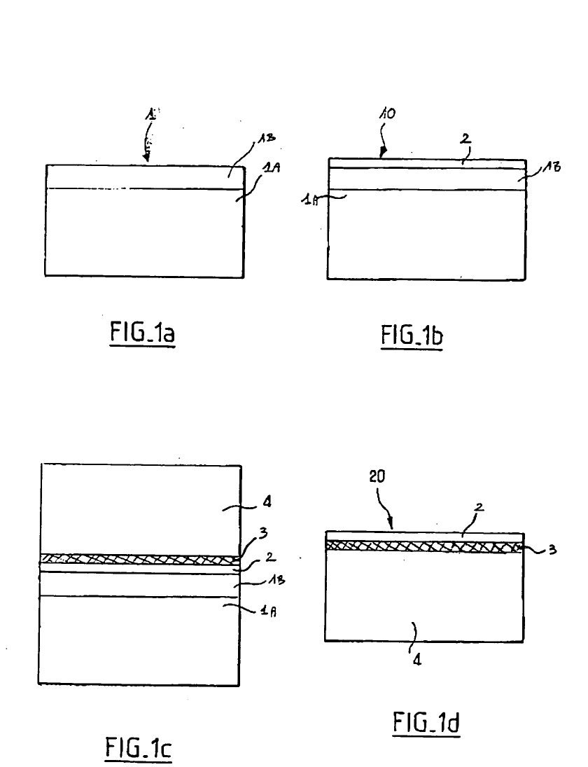

The non-limiting examples below of the processes according to the present invention describe the main stages or steps with reference to FIGS. 1 to 4.

Examples are also presented where the strained film 2 to be transferred to realize the SeOI structure is made of strained Si.

FIGS. 1a to 1d illustrate the stages of a first implementation of the process. FIG. 1a shows a donor wafer 1 whose function is to be a substrate upon which the strained film 2 is grown (with reference to FIG. 1b). In this embodiment, the donor wafer 1 is a ‘pseudo-substrate’ that includes a support substrate 1A made of monocrystalline Si and a buffer structure 1B which is interlaced with the strained film 2. The buffer structure 1B may be any structure behaving in the manner of a buffer layer. The buffer layer generally designates a transition layer between a first crystalline structure such as the support substrate 1A and a second crystalline structure such as the film 2, which functions to modify the properties of the material, such as the structural or stoichiometric properties, or surface atomic recombination. In a particular case of the buffer layer, a second crystalline structure can be produced having a mesh parameter that differs substantially from that of the support substrate 1A.

Advantageously, the surface of the buffer structure 1B has a substantially relaxed crystallographic structure and/or does not include a notable number of structural defects. In addition, the buffer layer performs at least one of the two following advantageous functions. First, it may decrease the density of defects in the upper layer, and second, it may provide a mesh parameter between two crystallographic structures of different mesh parameters.

To execute the second function above, the buffer layer has a first mesh parameter substantially identical to that of the support substrate 1A in the region of one of its faces, and has a second mesh parameter in the region of its other face. The buffer layer in the buffer structure 1B presents on its surface a mesh parameter that is substantially different to the mesh parameter of the support substrate 1A. Thus, the donor wafer 1 can have a layer having a mesh parameter different to that of the support substrate 1A. In certain applications the buffer layer can also prevent the overlying layer from containing an accumulation of defects and/or from undergoing noticeable constraints.

According to a first technique for realizing a buffer structure 1B, a buffer layer is formed having a mesh parameter that is modified progressively with thickness to establish the transition between the two mesh parameters. Such a layer is generally called a metamorphic layer. Such a buffer layer is advantageously made of SiGe with preferably a concentration of Ge growing progressively outward from the interface with the support substrate 1A. The buffer layer thickness is typically between 1 and 3 micrometers, for surface concentrations of Ge of less than 30%, to produce good structural surface looseness, and to confine defects associated with the difference in mesh parameter so that they are embedded.

Optionally, growth of an additional SiGe layer having a constant Ge composition, follows or precedes formation of the buffer layer, the whole forming the buffer structure 1B. The additional SiGe layer is substantially relaxed by the buffer layer, with an advantageously uniform Ge concentration that is substantially identical to that of the buffer layer in the vicinity of their interface. The concentration of germanium in the silicon inside the layer of relaxed SiGe is typically between 15% and 30% (i.e., x is 0.15 to 0.3). This 30% limitation is typical of current techniques, but the invention is operable with other values of x as high as 1. The additional layer has a thickness that may vary widely, according to each case, from 0.1 micron to 10 microns with a typical thickness being between 0.5 and 1 micron.

A second technique for realizing the buffer structure 1B is based on a technique for depositing a superficial layer on a support substrate 1A. The superficial layer has a nominal mesh parameter that is substantially different than the mesh parameter of the adjacent surface material of the support substrate 1A. The nominal mesh parameter means the mesh parameter of a material in its solid, monocrystalline and balanced form. This superficial layer is deposited to enable the deposited layer to be substantially exempt from plastic defects, such as dislocations.

This superficial layer includes a first part in contact with the support substrate 1A, which confines plastic defects, such as dislocations. It also includes a second part, relaxed or pseudo-relaxed by the first part, and having no or few plastic defects. The first part of the deposited superficial layer thus plays the role of a buffer layer.

The depositing technique employed to realize such a buffer layer can include variations in time and in the temperatures of chemical deposit compositions. The second technique produces a buffer layer having a chemical composition that is substantially constant with thickness, as opposed to a buffer layer created according to the first technique.

One or several layers can, however, be inserted between the buffer layer and the second part of the superficial layer. The buffer layer can also have a thickness that is less than the lower range of the thickness of the buffer layers produced according to the first technique.

U.S. Pat. No. 6,537,370 discloses an embodiment of such a buffer structure according to the latter technique. It includes depositing a first Ge or SiGe layer on a support substrate 1A of Si, and then, optionally, depositing a second additional layer. The second layer is used to improve the crystallographic quality of the overlaying film 2. U.S. Pat. No. 6,537,370 describes the second layer as SiGe (50/50) in the case where the first layer of the buffer layer is in Ge, and strained Si in the case where the first layer of the buffer layer is of SiGe.

The thickness of this buffer structure 1B can be on the order of 0.5 to 1 micron, which is less than the thickness of a buffer layer made according to the first technique. The donor wafer 1 has been produced in this manner, with the donor wafer 1 including the support substrate 1A in Si and the buffer structure 1B in Ge or in SiGe.

A third production technique for producing a buffer structure 1B includes a first stage consisting of depositing a layer 1B of strained SiGe on a support substrate 1A in Si, with the support substrate 1A and possibly the epitaxied layer 1B being included in the donor wafer 1. A second stage consists of implanting atomic samples, such as hydrogen and/or helium, having an implantation energy and a sample dosage chosen to form a perturbation zone in the thickness between the depth of the implant and the strained layer. A perturbation zone is defined as a zone having internal constraints which can form structural perturbations in the surrounding parts. These internal constraints are then susceptible to creating crystallographic perturbations in the overlying strained layer.

During the first stage the ranges of implant energy of H or He are typically between 12 and 25 keV. The implanted doses of H or He are typically between 10¹⁴ and 10¹⁷ cm⁻². Therefore, for example, H will preferably be used for the implant dosed at about 3.10¹⁶ cm⁻² with an energy of about 25 keV for a strained layer 1B at 15% Ge. In another example, H will preferably be used for the implant dosed at about 2.10¹⁶ cm⁻² with an energy of about 18 keV for a strained layer 1B at 30% Ge.

The atomic samples are implanted in the donor wafer 1 typically at a depth of between approximately 50 nm and about 100 nm.

To create or accentuate the perturbations of the perturbation zone, the buffer layer is produced according to this third technique by implementing a third stage by using a thermal energy contribution adapted and conveniently having parameters that cause at least relative relaxation of the elastic constraints of the layer 1B in strained SiGe so as to form a relaxed strained layer in SiGe. The thermal treatment is preferably utilized in an inert or oxidizing atmosphere. Therefore, a particular thermal treatment to be used for this type of donor wafer 1 is carried out at temperatures of between about 400° C. and 1000° C. over a period which can vary from about 30 seconds to about 60 minutes, and more particularly of approximately 5 minutes to approximately 15 minutes.

Therefore, the perturbation zone confines defects of the dislocation type, and adapts the mesh parameter of the support substrate 1A in Si to the nominal mesh parameter of the strained layer 1B in SiGe. It can therefore be considered here as a buffer layer.

A variant of this technique consists of forming the film in Si 2 on a layer 1B of strained SiGe prior to implantation of the particles. Implantation followed by a thermal treatment will then relax or pseudo-relax the layer of strained SiGe (as described hereinabove) and constrain the film 2. In this case, formation of the buffer layer and formation of the constraint in the film 2 are closely associated. For more information, reference can be made to B. Hollander and colleagues, in particular to the document entitled: “Strain relaxation of pseudomorphic Si₁₋ₓGeₓ/Si (100) heterostructures after hydrogen or helium ion implantation for virtual substrate fabrication” (Nuclear and Instruments and Methods, in Physics Research B 175-177 (2001) pages 357-367).

Irrespective of the structural configuration of the donor wafer 1 in this application of the process, the structure at the level of the interface includes the strained film 2 of a material made of crystalline Si₁₋ₓGeₓ having little or no crystallographic defects. The donor wafer 1 comprises an upper layer of sufficient thickness to impose its mesh parameter on the strained film 2 which will be overlying it, without the latter substantially influencing the crystalline structure of the upper layer of the donor wafer 1.

A light finishing stage for the surface of the donor wafer 1 is advantageously performed to improve the surface quality. Suitable surface finishing techniques may include polishing, chemical etching, abrasion, mechanical-chemical planarizing (CMP), sacrificial oxidation, bombardment of atomic samples, or other smoothing techniques.

With reference to FIG. 1b, a Si film 2 is grown on the Si₁₋ₓGeₓ growth substrate of the donor wafer 1. The Si film 2 is advantageously formed by epitaxy by using known techniques such as CVD and MBE techniques (respective abbreviations of Chemical Vapor Deposition and Molecular Beam Epitaxy). Since the silicon has a mesh parameter different than that of germanium, the film 2 is influenced by the substrate material Si₁₋ₓGeₓ to augment its nominal mesh parameter to appear substantially identical to that of its growth substrate and thus presents internal tension constraints. These modifications to its internal crystallographic structure boosts the mobility of the charged particles (such as the holes and electrons) by modifying the structure of the energy bands of the silicon crystal. The desired electric properties for this film 2 are thus obtained.

For a layer to be elastically strained, its thickness must not surpass a critical thickness of elastic constraint. Beyond the critical thickness, plastic constraints and elastic relaxations can appear in the film 2 which would substantially deteriorate its electrical properties. The critical thickness of elastic constraints depends mainly on the material selected for the strained layer and on the difference of the mesh parameter with the material of the crystalline structure on which it has been formed. Therefore, since silicon has a mesh parameter of approximately 4.2% less than that of the germanium, the discord in mesh between the silicon of the film 2 and the Si₁₋ₓGeₓ growth support is such that it implies a critical thickness of the film 2 of between approximately 100 Å and 2000 Å, depending on the value of x. For example, if x=0.2, then the strained Si film 2 is on the order of about 200 Å.

The critical thickness may also depend on growth parameters such as the temperature at which the film 2 was formed, the nucleation sites from which it was epitaxied, or the growth techniques employed (for example CVD or MBE).

Values of critical thickness of a Si film 2 epitaxied on a Si₁₋ₓGeₓ growth substrate are presented, for example, in a document entitled “High-mobility Si and Ge structures” by Friedrich Schaffler (Semiconductor Science Technology, 12 (1997) pages 1515-1549). The thickness of the strained Si film 2 is thus typically a few hundred angstroms, and preferably in the range of about 100 and about 500 Å.

Once it is formed, the film 2 thus has a mesh parameter substantially close to that of the Si₁₋ₓGeₓ and presents elastic constraints in tension.

Referring to FIG. 1b, the donor wafer 1 and film 2 together form a pre-adhesion wafer 10. With reference to FIG. 1c, the pre-adhesion wafer 10 is shown adhered or bonded to a receptor substrate 4. Prior to such adhesion, at least one insulating layer 3 made of an electrically insulating material is formed on the surface of the pre-adhesion wafer 10 and/or on the surface of the receptor substrate 4. The material selected for the insulating layer 3 is one that has a viscosity temperature TG greater than the viscosity temperature T_{GSiO2} of the SiO₂.

The value of viscosity temperature T_{GSiO2} of the SiO₂ can vary substantially according to certain criteria. For example, it can vary due to the production technique used to produce the layer of SiO₂. If the layer is produced by thermal oxidation (whether in a dry or humid atmosphere, and whether or not associated with the use of chemical samples), then the viscosity temperature T_{GSiO2} is on the order of approximately 1100° C. to approximately 1150° C. In the case of a layer formed by depositing SiO₂, the viscosity temperature T_{GSiO2} is in general less than 1110° C. This viscosity temperature may also depend upon the parameters for producing the SeOI structure, such as the energy used to activate the surfaces to be attached prior to adhesion, and may also depend upon structural parameters, such as the charge coefficient of constraints presented by the film 2. The viscosity temperature T_{GSiO2} of the SiO₂ can thus reach as much as 1100° C. to 1150° C.

If the viscosity temperature T_{G} is a theoretical thermal limit beyond which the elastic constraints seem to relax to a large extent, initial relaxations of constraints can appear before reaching T_{G} at temperatures less than T_{G} (and typically from approximately 100° C. to 200° C. less), the percentage of relaxation being nevertheless more and more important as T_{G} is approached. The insulating layer 3 has two principal functions: to electrically insulate the receptor substrate 4 from the film 2, especially in the final SeOI structure 20 (see FIG. 1d); and to keep the elastic constraints in the film 2 at high temperatures (greater than approximately 950° C. to 1000° C.). This insulating layer 3 can also have particularly significant adhesive properties that can be exploited during the adhesion stage. The insulating layer 3 can be formed by direct deposit onto the surface in question or by a chemical reaction between atomic samples of the surface in question with gaseous samples in a controlled atmosphere. In a first advantageous case, the material of the insulating layer 3 is made of Si₃N₄. A layer of Si₃N₄ thus has a temperature T_{G} which is greater than about 1500° C. The insulating layer of Si₃N₄ can be formed by nitration with the silicon material of the film 2 and/or with the silicon material of the receptor substrate 4 (if the latter contains any on the surface), or by depositing a nitride layer by a CVD technique on a surface.

It should be noted that the Si₃N₄ has adhesion properties almost equivalent to the adhesion properties of the SiO₂ in terms of adhesion energy and transfer quality. This has been observed in the case of utilizing a SMART-CUT® process, with reference for example to the document entitled “From SOI to SOIM Technology: application for specific semiconductor processes” by 0. Rayssac and colleagues (in SOI Technology and Devices X, PV 01-03 ecs Proceedings, Pedington, and J (2001)).

In a second advantageous case, the insulating layer 3 material is SiO^{y}N_{z}. During formation of an insulating layer 3 of SiO_{y}N_{z} the value of z can be advantageously manipulated, so that the viscosity temperature T_{G} can evolve or change, which for this material is substantially a function of the nitrogen composition. Therefore, with a growing composition z, it is possible to have the viscosity temperature T_{G} of the insulating layer 3 change typically between a T_{G} on the order of that of the SiO₂ (which may vary around 1100° C.) and a T_{G} on the order of that of the Si₃N₄. By manipulating the y variable, a wide range of T_{G} temperatures can be covered. Thus, it is possible to choose T_{G} by selecting a material that has a TG value between that of SiO₂ and Si₃N 4. The value of the y and z variables of the expression SiO_{y}N_{z} do not only reflect the percentage of O replaced by N, but also the number of atoms of O and N for a single atom of Si. This relationship is complex and cannot be adequately expressed by assigning exact values to the y and z parameters, and thus the expression SiO_{y}N_{z} is used to represent the relationship. As noted above, y and z can vary from 0 to an integer, e.g., y=3 and z=4 for Si₃N₄, but both y and z cannot be 0 simultaneously. Moreover, there are no preferred values, as the y and z parameters are design variables. For example, in some cases SiO₂ would be preferred while in other cases Si₃N 4 would be used, and yet in other cases a material in between expressed as SiO_{y}N_{z} would be chosen.

The temperature values T_{G} of the insulating layer 3, if they depend essentially on the material of the vitreous layer, can also fluctuate according to the conditions by which it was formed. In an advantageous case, the conditions for forming the insulating layer 3 can be adapted in a controlled manner so as to select a viscosity temperature T_{G} as desired that is greater than T_{GSiO2}. The deposit parameters, such as temperature, time, dosage and potential of the gaseous atmosphere, etc. can thus be varied. Doping elements can also be added to the main gaseous elements contained in the vitrification atmosphere, such as boron and phosphorous, as these can reduce the viscosity temperature T_{G}.

After one or more insulating layers 3 are formed on one or the two surfaces that are to be adhered together, a finishing stage is advantageously implemented on these two surfaces. For example, one of the known finishing techniques could be utilized, in order to smooth the surfaces as much as possible.

Adhesion occurs when the adhesion surfaces of the pre-adhesion wafer 10 and the receptor substrate 4 contact each other. Thus, the bonding or adhesion operation is carried out by contacting the surfaces to be adhered together. The adhesion bonds are preferably molecular and can be achieved by exploiting the hydrophilic properties of the surfaces. To accentuate the hydrophilic properties of the surfaces, chemical cleaning of the two structures to be adhered can be done in baths, for example, by using a SC1 treatment that is well-known to one of skill in the art.

The adhered assembly can be annealed to reinforce the adhesion bonds, by modifying the nature of the adhesion bonds, such as the covalence bonds or other bonds. For more information concerning adhesion techniques, reference can be made in particular to the document entitled “Semiconductor Wafer Bonding” (Science and technology, Interscience Technology) by Q. Y. Tong and U. Gösele, Wiley Publishers.

FIG. 1d illustrates the SeOI structure obtained after the donor wafer 1 is detached or removed. According to a first method, all or part of the donor wafer 1 is detached at a weakened zone that was previously formed in the donor wafer 1. This weakened zone is substantially parallel to the adhesion surface, and can be broken by supplying energy, such as by heating or providing mechanical forces.

According to a first implementation, a technique called SMART-CUT® is used to provide the weakened zone, which includes implantation of atomic particles in the donor wafer 1, at the weakened zone. The implanted particles can be hydrogen, helium, a mixture of these two particles or other atomic species. The implantation process preferably takes place just before the adhesion step.

The energy used to conduct the implantation process is selected such that the particles, implanted via the surface of the insulating layer 3 (in the event where it is formed on the donor wafer 1), pass through the thickness of the insulating layer 3, the thickness of the strained film 2 and a preset thickness of the upper part of the donor wafer 1. It is preferable to implant particles sufficiently deeply in the donor wafer 1 so that the strained film 2 does not suffer damage during the detachment stage when the donor wafer 1 is detached. The depth of implantation in the donor wafer 1 is typically at least approximately 1000 Å. The brittleness or weakness of the bonds in the weakened zone is determined mainly by selecting the dosage of the implanted particles, with the dosage being typically between 10¹⁶ cm⁻² and 10¹⁷ cm⁻², and more precisely between approximately 2.10¹⁶ cm⁻² and approximately 7.10¹⁶ cm⁻². As noted above, mechanical and/or thermal energy can be used to effect detachment at the weakened zone.

For more information concerning the SMART-CUT® process, reference can be made to the document entitled “Silicon-On-Insulator Technology”: Materials to VLSI, 2nd Edition by J.-P. Colinge, edited by Kluwer Academic Publishers, pages 50 to 51.

In accordance with a second mode of producing a weakened zone, a technique described in U.S. Pat. No. 6,100,166 can be used. In this case, the weakened zone is created before formation of the film 2, and during formation of the donor wafer 1. In this case, forming the weakened zone includes forming a porous layer on a substrate, and growing one or more layers on the porous layer. The substrate-porous layer-layer(s) structure includes the donor wafer 1, and the porous layer is the weakened zone of the donor wafer 1. Thermal and/or mechanical energy can then be applied at the porous weakened zone to detach the support substrate 1A from the overlying layer(s) on the porous layer.

The preferred technique for removing material at the weakened zone, realized according to one of the two of the non-limiting examples given above, therefore allows a significant part of the donor wafer 1 to be withdrawn rapidly and en bloc or altogether. Such operations also allow the withdrawn part of the donor wafer 1 to be reused in another process, such as for example, another a process according to the present technique. Therefore, a strained film may be reformed on the withdrawn part of the donor wafer, and possibly on other parts of the donor wafer, and/or other layers can be formed, preferably after polishing the surface of the withdrawn part. A surface finishing stage may be used to allow the remaining part of the Si₁₋ₓGeₓ donor wafer to be withdrawn. For example, the withdrawn donor wafer 1 may be reduced by different finishing techniques such as CMP polishing, abrasion, thermal RTA annealing, sacrificial oxidation, and chemical etching, either singly or in combination.

In an advantageous manner, removing the finishing material utilizes, at least at the end of the stage, selective chemical etching, which may be combined with the use of mechanical means. Therefore, selective etching solutions for the SiGe vis-a-vis the Si, such as a solution comprising HF:H₂O₂:CH₃COOH (selectivity of around 1:000) can be used to withdraw the remaining part of the Si₁₋ₓGeₓ.

The film 2 has a crystalline structure and homogenous properties in thickness close to those it had after growth on the donor wafer 1. After the adhesion stage, a second technique could be used to remove material and to remove the donor substrate 1 without detachment and without having a weakened zone. Such a technique may consist of implementing chemical and/or mechanical and/or mechanical-chemical etching. For example, an etch-back type process could be used to selectively etch the materials of the donor wafer 1 to be removed. This technique consists of etching the donor substrate 1 from behind, that is, from the free face of the donor wafer 1. Wet etching which uses etching solutions adapted to the materials to be removed can also be used. Dry etching, such as plasma etching or pulverization etching, can also be used to remove material. The etching can also be purely chemical or electrochemical or photoelectrochemical.

An etching process can be preceded or followed by a mechanical attack of the donor wafer 1, such as lapping, polishing, mechanical, or pulverization etching of atomic samples. The etching process can also be accompanied by mechanical attack, such as polishing optionally combined with a mechanical abrasive action in a CMP process.

All the abovementioned techniques for removing material from the donor wafer 1 are proposed by way of example, and thus these cited methods are not limiting, because the invention is suitable for use with all types of techniques that are capable of removing material from the donor wafer 1 as per the described process.

In FIG. 1d, an SOI structure 20 is obtained wherein the semiconductor part (that is, the film 2) is made of strained Si, and the insulating part (that is, the insulating layer 3) has a viscosity temperature T_{G} that is greater than the viscosity temperature T_{GSiO2} and is made, for example, of Si₃N₄ or SiO_{y}N_{z}. The SOI structure 20 permits thermal treatment at temperatures greater than 950° C. to 1000° C., such as certain treatments to be utilized for producing constituents in the film 2, without the strained material undergoing significant elastic relaxation, as is the case for SOI structures having an insulating part in SiO₂.

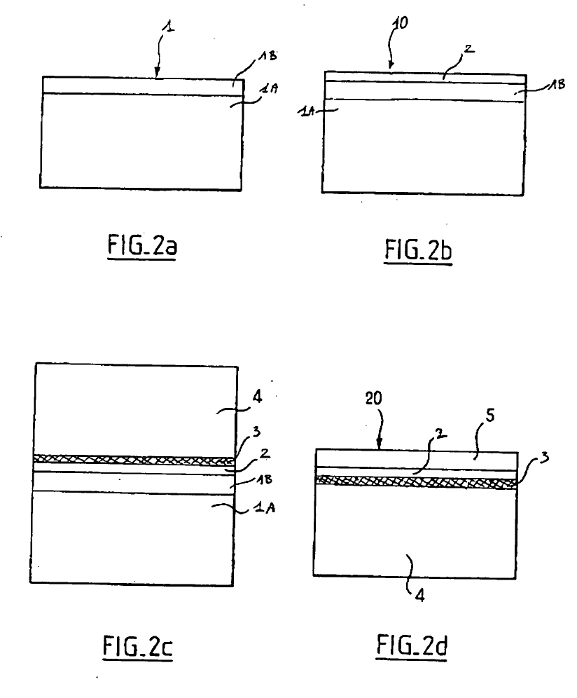

A second embodiment of the present process is presented with reference to FIGS. 2a to 2d. This overall process is substantially the same as that described with reference to FIGS. 1a to 1d, with the exception of the removal of the donor wafer 1.

In particular, only part of the donor wafer 1 is removed, with the remaining part of the donor wafer 1 forming an upper layer 5 on the structure 20 (see FIG. 2d). The techniques used to remove material are substantially the same as those disclosed above with reference to FIG. 1d. However, techniques are utilized to conserve the upper layer 5 so that the upper layer includes at least a portion of the buffer structure 1B. This process may be advantageously used for a buffer structure 1B that has been produced according to either of the first or the second buffer forming techniques. This process is particularly advantageous if one or the other of the two types of buffer structures (the two types of buffer structures associated, respectively, to the two production techniques) comprises in its upper part a layer of Si₁₋ₓGeₓ having a composition which is substantially constant without too many crystallographic defects. In such a case, the technique used to remove material is controlled so that the upper layer 5 includes at least a portion of the Si₁₋ₓGeₓ layer. The result is therefore a structure 20 comprising an upper layer 5 of the quality Si₁₋ₓGeₓ, where x may vary between 0 and 1.

After material has been removed, a surface finishing stage is advantageously used to reduce the roughness of the surface and minimize the unevenness in the thickness of the upper layer 5 of Si₁₋ₓGeₓ. For example, techniques such as polishing, abrasion, CMP planarizing, and chemical etching, could be used either singly or in combination.

According to a variant, the donor wafer 1 includes an etching stop layer located between the upper layer 5 and the rest of the donor wafer 1. This effectively terminates the finishing stage by selective etching at this stop layer, and obtains an upper layer 5 which is particularly homogeneous in thickness and that has a smooth surface. With reference to FIG. 2d, the final result is a Si₁₋ₓGeₓ/SOI structure 20 wherein the semiconductor part (that is, the upper layer 5 and the film 2) comprises strained Si, and wherein the insulating part (that is, the insulating layer 3) has a viscosity temperature T_{G} greater than the viscosity temperature T_{GSiO2}, such as for example that of Si₃N₄ or SiO_{y}N_{z}. The structure 20 thus allows thermal treatment at temperatures greater than 950° C. to 1000°° C., without losing too many constraints in the film 2.

In a particular case where thermal treatment occurs at a temperature and for a period greater than a temperature and a reference period from which the Ge diffuses in the Si, the Ge contained in the upper layer 5 can diffuse in the film 2. In certain cases this diffusion effect, if well controlled, can be desirable. In fact, diffusion can be controlled such that particles of Ge are distributed uniformly in the entirety of the two layers 2 and 5, forming a single layer of SiGe having a substantially uniform Ge concentration. There is a discussion of this feature in U.S. Pat. No. 5,461,243, at column 3, lines 48 to 58.

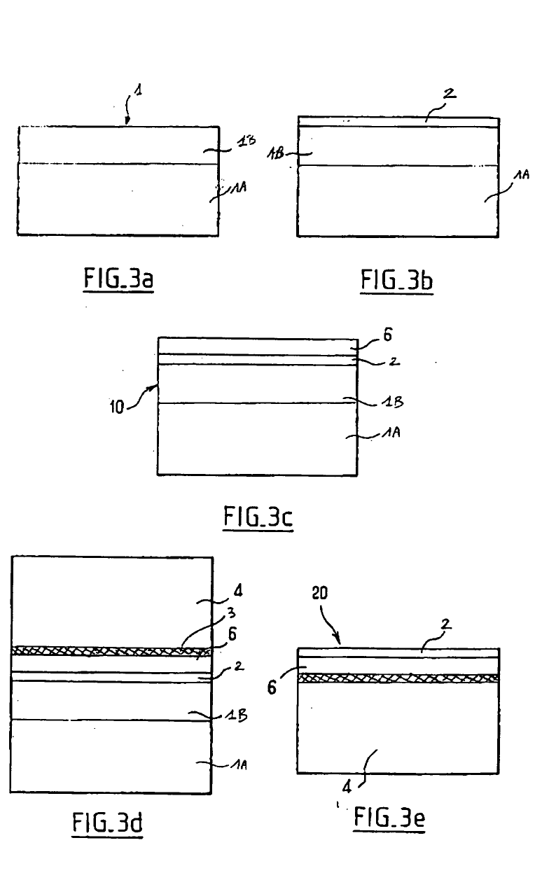

A third process according to the invention is presented with reference to FIGS. 3a to 3e. This overall process is the same as that described with reference to FIGS. 1a to 1d, except that it includes an additional stage of crystalline growth of an additional layer 6 which will be explained with reference to FIG. 3c. This additional layer 6 is epitaxially grown, for example by using a CVD or MBE technique, on the strained Si film 2.

The additional layer 6 may be made of any type of material. However, the material is preferably Si_{1-z}Ge_{z} with a composition z substantially identical to the composition x of Si₁₋ₓGeₓ present on the surface of the buffer structure 1B, such that the additional layer 6 is relaxed or pseudo-relaxed.

After the growth of the additional layer 6, the insulating layer 3 is formed at the level of the additional layer 6 and/or on the surface of the receptor substrate 4. In the situation where the insulating layer 3 is formed on the surface of the additional layer 6, it can be produced by direct deposit, or by a chemical reaction between atomic particles and the material making up the surface of the additional layer 6, with gaseous samples in a controlled atmosphere. An insulating layer can be formed by nitration of the silicon-germanium of the additional layer 6 of Si_{1-z}Ge_{z}. In this case, the value of z is close to x value and would be between 0 and 1, and preferably between 0.8 and 0.6.

FIG. 3d shows the adhesion stage, and FIG. 3e shows the removal of material. These FIGS. 3d and 3e are substantially identical to those of FIGS. 1c and 1d. With reference to FIG. 3e, the final result is a strained Si/SGOI structure 20 wherein the semiconductor part (that is, the film 2 and the additional layer 6) includes strained Si, and wherein the insulating part (that is, the insulating layer 3) has a viscosity temperature T_{G} greater than that of SiO2, such as for example SiₓGe_{y}N_{z}. The structure 20 therefore allows thermal treatment at temperatures greater than about 950° C. to about 1000° C. to be undertaken, without inducing too many constraints in the film 2.

The Ge contained in the additional layer 6 can diffuse into the film 2 if a thermal treatment is conducted at a temperature and for a time period that is greater than a temperature and reference period in which Ge diffuses into Si. In certain cases, such a diffusion effect can be desirable, if well controlled. Diffusion can be controlled such that the particles of Ge are uniformly distributed in the entirety of the two layers 2 and 6 to form a single layer of SiGe having a Ge concentration which is substantially uniform Again, this feature is described in U.S. Pat. No. 5,461,243, at column 3, lines 48 to 58.

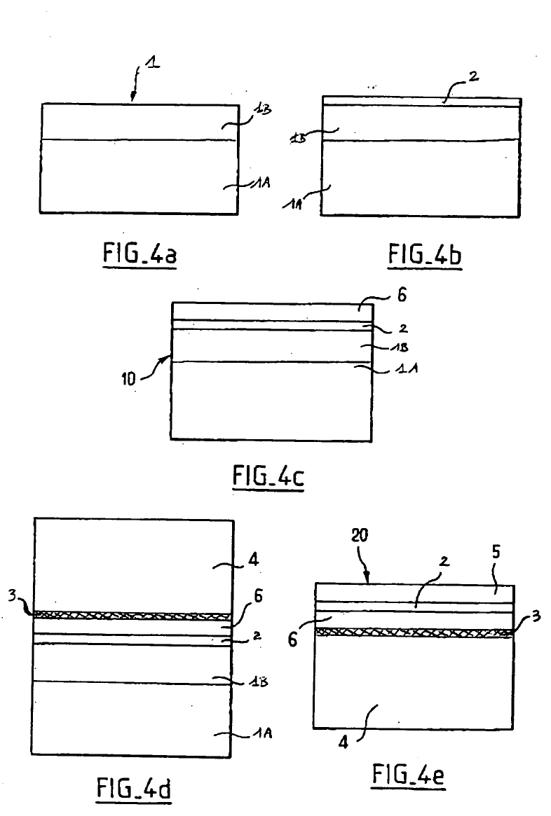

A fourth process is shown in FIGS. 4a to 4e. In particular, referring to FIGS. 4c and 4e the overall process is substantially the same as that described with reference to FIGS. 1a to 1d, with the following exceptions. Removing material from the donor wafer 1 in this case relates only to a portion of the donor wafer 1, with the result that an upper layer 5 remains in the upper part of the final structure 20 (see FIG. 4e). Moreover, this process includes an additional stage of crystalline growth of an additional layer 6 which can be seen in FIG. 4c. This process includes a stage that is identical to that described with reference to FIG. 2d, forming an upper layer 5 (see FIG. 4e), and includes a stage that is identical to that described with reference to FIG. 3c, forming an additional layer 6 (see FIG. 4e) that is inserted between the film 2 and the receptor substrate 4. The means for forming these two layers 5 and 6, as well as the possibilities for controlling their structure and their effect on the final structure are thus essentially the same as those described in the processes with reference to FIGS. 2a to 2d and FIGS. 3a to 3e.

FIG. 4e shows the final result which is a SiGe/strained Si/SGOI structure 20 wherein the semiconductor part (that is, the film 2 and the additional layer 6) comprises strained Si, and wherein the insulating part (that is, the insulating layer 3) has a viscosity temperature greater than 950° C. to 1000° C., and thus may be a material such as, for example, SiₓGe_{y}N_{z} as defined above. The structure 20 can then undergo thermal treatment at temperatures greater than 950° C. without losing too many constraints in the film 2.

The Ge contained in the additional layer 6 and in the upper layer 5 will diffuse into the film 2 if a thermal treatment is conducted at a temperature and for a period that is greater than a temperature and reference period in which Ge diffuses into the Si. In certain cases this diffusion effect is desirable, if well controlled. Such diffusion can be controlled such that the particles of Ge are uniformly distributed over the entirety of the three layers 2, 5 and 6 to form a single layer of SiGe that has a substantially uniform Ge concentration. Again, U.S. Pat. No. 5,461,243 at column 3, lines 48 to 58 can be reviewed for further details of this feature.

According to any one of the four preferred processes described herein, and according to an equivalent of the controlled diffusion stage, the various stages for producing the components can be integrated into or succeed thermal treatment. Therefore, preparation stages for the production of components can be implemented during the process, without altering the percentage of constraints in the film 2. Such a preparation stage can be used at the level of the strained Si film 2 of the SGOI structure shown in FIG. 1d, at the upper layer 5 of relaxed Si₁₋ₓGeₓ and/or the film 2 of the SiGe/SOI structure shown in FIG. 2d, at the film 2 and/or the additional layer 6 of relaxed Si₁₋ₓGeₓ of the strained Si/SGOI structure shown in FIG. 3e, and at the upper layer 5 of relaxed Si₁₋ₓGeₓ and/or the film 2 and/or the additional layer 6 of relaxed Si_{1-z}Ge_{z} of the SiGe/Si strained SGOI structure shown in FIG. 4e. In addition, local treatment designed to etch patterns in the layers, for example by lithography, photolithography, reactive-ion etching or by any other etching with pattern masking can be utilized.

One or more stages for producing components, such as transistors, in the strained Si film 2 (or in the layer of relaxed SiGe in the case where the latter is not covered with a layer of strained Si) can in particular be implemented without altering the percentage of constraints of the film 2. The techniques described above are exemplary only, and do not limit the invention because the invention extends to all types of techniques capable of using a process according to the invention. One or more epitaxy processes can be used on the final structure 20 (with reference to FIGS. 1d, 2d, 3e, 4e). For example, epitaxy of a layer of SiGe or SiGeC, or epitaxy of a layer of Si or strained SiC, or successive epitaxial layers of SiGe or SiGeC and layers of Si or strained SIC alternating to form a multilayer structure could be used. Accordingly, and in particular, the film 2 may be thickened by epitaxy of Si on the film 2 after the film has been transferred.

It has been observed that the strained Si film 2 can be made to be thicker than the standard critical thickness of the Si, without losing elastic constraints. The standard critical thickness of the Si can be found from the value of the percentage of constraints of the film 2 and from the fact that this percentage of constraints can be associated directly with the concentration of Ge in the Si₁₋ₓGeₓ on the pseudo-substrate (i.e. the value x) on which the film 2 was or would be epitaxied (if the percentage of constraints of the film 2 was not modified since formation, the concentration x of the associated Ge is that of the pseudo-substrate of Si₁₋ₓGeₓ on which the film 2 was epitaxied before being transferred). The value of the standard critical thickness of the Si of the film 2 can thus be associated directly with the concentration of Ge of the pseudo-substrate of Si₁₋ₓGeₓ on which the film 2 was or would be epitaxied. Examples of standard critical thickness of the Si can be found in particular in the article “High-Mobility Si and Ge Structures” by Friedrich Schaffler (Semiconductor Science Technology, 12 (1997) pages 1515-1549).

Therefore, it is noted that, in a structure comprising a layer of material that becomes viscous at a viscous temperature T_{G}, and a strained Si film 2 on the viscous material, the critical thickness of the film 2 (beyond which the film 2 is no longer mainly elastically strained) is typically more significant than the standard critical thickness of the Si. Therefore, experience has shown that it is possible to increase the thickness of the film 2 to approximately 60 nanometers, without there being substantial loss of elastic constraints intrinsic to the film 2. Such a thick film 2 can then be used as an active layer (taking advantage of the considerable mobility of electrons exhibited by such a material).

Once the final structure is achieved, with or without thickening, finishing treatment can be put into practice, such as annealing, for example. The present invention is not limited to a strained Si film 2, but also extends to alloys Si_{1-y}Ge_{y} including values of y between 0 and 1, capable of being strained by a growth support of Si₁₋ₓGeₓ including values of x between 0 and 1 (on the surface of the donor wafer 1) and wherein x and y are different values.

Therefore, in a first particular application, the donor wafer 1 would be a solid substrate of Si on which a film 2 of strained Si₁₋ₓGeₓ would be grown (on the solid substrate). A weakened zone is formed in the solid substrate, and thus transfer to form a final semiconductor-on-insulator structure is thus identical to the process according to the present invention described above.

In a second particular application, the donor wafer 1 would be a bulk substrate of Si₁₋ₓGeₓ, having x values between approximately 0.7 and 1, on which a Si film 2 or Si₁₋ₓGeₓ film would be grown, with these materials being strained by the solid substrate. Since transfer to form a final semiconductor-on-insulator structure is identical to the process according to the present invention described hereinabove, the weakened zone is formed in the solid substrate.

In a third particular application, a buffer structure 1B of Si_{1-z}Ge_{z} (with z diminishing gradually in thickness) is inserted between the solid substrate 1A of Si₁₋ₓGeₓ and the film 2 (in strained Si or strained Si₁₋ₓGeₓ) in order to find the constraint coefficient of the desired film 2. The final value of z could, for example, be 0.5. The result is that the thin film on the buffer structure is composed of strained Si or strained SiGe, for example, Si_{1-y}Ge_{y} with y being greater or equal to 0 and less than or equal to one, and y being inferior to the final value of z (to be strained) of the buffer structure, down to 0 (strained silicon). For example, a Ge bulk substrate may include a buffer layer gradually growing from 100% Ge (z=1) to 50% Ge (z=5), and then a final layer of strained Si (y=0) or a strained layer of SiGe to 20% (y=0.2)

In general, the strained film 2 can be of other types of material, such as alloys of Group (III-V) or Group (II-VI), or of other semiconductor materials capable of being used by a process according to the present invention and being in a semiconductor-on-insulator structure according to the present invention. For example, the film 2 can be made of a nitride material, such as an alloy (Al, Ga, In)—(N), which has been initially formed on a donor wafer 1 comprised of a solid substrate or a pseudo-substrate in sapphire or SiC.

In the layers of semiconductors discussed herein, other elements or constituents can be added, such as carbon at a concentration of carbon in a particular layer that may be substantially less than or equal to 50% or, more particularly, at a concentration less than or equal to 5%.

1. A semiconductor-on-insulator structure comprising:
a substrate;
an insulating layer on the substrate; and
a semiconductor layer on the insulating layer and being made of a material that includes elastic constraints therein;
wherein the insulating layer includes an electrically insulating material to electrically insulate the semiconductor layer from materials that contact the insulating layer, with the material of the insulating layer having a viscosity temperature T_{G} that is sufficiently high so as to protect the semiconductor layer from loss of the elastic constraints when the structure is exposed to a temperature of about 950° C. or more.

2. The semiconductor-on-insulator structure of claim 1 wherein the semiconductor layer comprises silicon, and the material of the insulator has a viscosity temperature T_{G} that is greater than the viscosity temperature T_{GSiO2} of silicon oxide (SiO₂).

3. The semiconductor-on-insulator structure of claim 2 wherein the semiconductor layer comprises a film of strained material.

4. The semiconductor-on-insulator structure of claim 3 wherein the strained film comprises Si_{1-y}Ge_{y}, where y is between 0 and 1.

5. The semiconductor-on-insulator structure of claim 3 further comprising at least one layer of relaxed or pseudo-relaxed material on the strained film.

6. The semiconductor-on-insulator structure of claim 5 wherein the layer of relaxed or pseudo-relaxed semiconductor material is located between the strained film and the insulating layer.

7. The semiconductor-on-insulator structure of claim 5 wherein the strained film is located between the layer of relaxed or pseudo-relaxed semiconductor material and the insulating layer.

8. The semiconductor-on-insulator structure of claim 5 which further comprises a first layer of a relaxed or pseudo-relaxed material situated between the strained film and the insulating layer and a second layer of relaxed or pseudo-relaxed material on an opposite side of the strained film.

9. The semiconductor-on-insulator structure of claim 5 wherein the relaxed or pseudo-relaxed material comprises Si₁₋ₓGeₓ, where x is between 0 and 1.

10. The semiconductor-on-insulator structure of claim 1 wherein the viscosity temperature T_{G} is greater than approximately 1000° C.

11. The semiconductor-on-insulator structure of claim 2 wherein the viscosity temperature T_{GsiO2} is greater than approximately 1110° C.

12. The semiconductor-on-insulator structure of claim 1 wherein the insulating layer comprises Si₃N₄ or SiO_{y}N_{z} where y and z each is 0 or an integer but both y and z cannot be 0 simultaneously.

13. The semiconductor-on-insulator structure of claim 1 wherein the insulating layer comprises Si_{1-z}Ge_{z}, wherein z is between 0 and 1.

14. The semiconductor-on-insulator structure of claim 1 wherein the semiconductor layer comprises
a strained Si_{1-y}Ge_{y} layer; and
a layer of relaxed or pseudo-relaxed Si₁₋ₓGeₓ on the strained layer, wherein x and y are between 0 and 1 and are not equal to each other.

15. The semiconductor-on-insulator structure of claim 1 wherein the semiconductor layer comprises:
a layer of relaxed or pseudo-relaxed Si_{1-z}Ge_{z}; and
a layer of strained Si_{1-y}Ge_{y} on the relaxed or pseudo-relaxed layer, wherein y and z are between 0 and 1 and are not equal to each other.

16. The semiconductor-on-insulator structure of claim 1 wherein the semiconductor layer comprises:
a layer of relaxed or pseudo-relaxed Si_{1-z}Ge_{z};
a layer of strained Si_{1-y}Ge_{y}; and
a layer of relaxed or pseudo-relaxed Si₁₋ₓGeₓ, wherein x, y and z are between 0 and 1, x, y and z are not equal to each other, and x and y are approximately the same value.

17. The semiconductor-on-insulator structure of claim 1 wherein the substrate is made of a crystalline material having a nominal mesh parameter, and the material of the semiconductor material has a nominal mesh parameter that is substantially different from that of the substrate.

18. A process for producing a semiconductor-on-insulator structure which comprises:
providing on a substrate an insulating layer that includes an electrically insulating material;
providing a semiconductor layer made of a material that includes elastic constraints therein; and
bonding the insulating and semiconductor layers together to form a structure wherein the insulating layer electrically insulates the semiconductor layer from materials that contact the insulating layer, and the material of the insulating layer has a viscosity temperature T_{G} that is sufficiently high so as to protect the semiconductor layer from loss of the elastic constraints when the structure is exposed to a temperature of about 950° C. or more.

19. The process of claim 18 wherein the substrate is a donor wafer of crystalline material having a mesh parameter, the semiconductor layer is a strained layer, and the method further comprises selecting the semiconductor material to have a nominal mesh parameter that is substantially different from that of the donor wafer, and growing the strained layer of semiconductor material on the donor wafer to a thickness that is sufficiently thin to retain elastic strain therein.

20. The process of claim 19 which further comprises providing the insulating layer on a receptor substrate; bonding the insulating layer to the semiconductor layer such that the strained and the insulator layers are positioned between the receptor substrate and the donor wafer; and detaching at least a portion of the donor wafer to form the semiconductor-on-insulator structure.

21. The process of claim 19 which further comprises forming the insulating layer on the strained layer; bonding the insulating layer to a receptor substrate such that the strained and the insulator layers are positioned between the receptor substrate and the donor wafer; and detaching at least a portion of the donor wafer to form the semiconductor-on-insulator structure.

22. The process of claim 19 which further comprises growing a relaxed or pseudo-relaxed semiconductor layer on the strained layer.

23. The process of claim 18 wherein the electrically insulating layer is provided by nitration of a silicon material.

24. The process of claim 23 wherein the insulating layer comprises Si₃N₄ or SiO_{y}N_{z} where y and z each is 0 or an integer but both y and z cannot be 0 simultaneously.

25. The process of claim 18 wherein the insulating layer comprises Si_{1-z}Ge_{z}, wherein z is between 0 and 1.

26. The process of claim 18 wherein the electrically insulating layer is deposited on at least one surface that is to be subsequently bonded.

27. The process of claim 19 which further comprises transferring a portion of the donor wafer to the receptor substrate to form at least a part of an upper layer of crystalline material.

28. The process of claim 27 which further comprises, before the transfer, implanting atomic particles into the donor wafer at a preset depth to create a weakened zone in the vicinity of the depth of the implant, and wherein detachment occurs at the weakened zone.

29. The process of claim 27 further comprising, prior to growing the strained layer, forming a porous layer on a crystalline support substrate, growing a crystalline layer on the porous layer, wherein the support substrate, porous layer and crystalline layer together forming the donor wafer, and the porous layer being a weakened zone in the donor wafer, and wherein detachment occurs at the weakened zone.

30. The process of claim 27 which further comprises finishing the surface of the portion of the donor wafer that is transferred to the receptor substrate.

31. The process of claim 27 which further comprises removing the portion of the donor wafer transferred to the receptor substrate.

32. The process of claim 31 wherein removal of the portion of the donor wafer occurs by using selective chemical etching.
